(19) United States
(12) Patent Application Publication
(10) Pub. No.: US 2025/0172603 A1
(43) Pub. Date: May 29, 2025

(54) Method for Quickly Identifying and Responding Weak Point-Associated Power Flow Based on Sensitivity Factor

(71) Applicant: Guizhou Power Grid Co., Ltd., Guiyang (CN)

(72) Inventors: Qingsheng LI, Guiyang (CN); Yu ZHANG, Guiyang (CN); Zhaofeng ZHANG, Guiyang (CN); Xueyong TANG, Guiyang (CN); Jiahuan LONG, Guiyang (CN); Bin HU, Guiyang (CN); Julong CHEN, Guiyang (CN); Jierui YANG, Guiyang (CN); Zhen LI, Guiyang (CN); Jinsen LIU, Guiyang (CN); Ning LUO, Guiyang (CN); Yongqing ZHU, Guiyang (CN); Yang LUO, Guiyang (CN); Huijiang WAN, Guiyang (CN); Haidong PANG, Guiyang (CN); Jun AO, Guiyang (CN); Jianglong WU, Guiyang (CN)

(21) Appl. No.: 19/011,368

(22) Filed: Jan. 6, 2025

Related U.S. Application Data
(63) Continuation of application No. PCT/CN2024/135874, filed on Nov. 29, 2024.

(30) Foreign Application Priority Data
Nov. 29, 2023 (CN) 2023116110674

(51) Int. Cl. G01R 31/08; H02J 3/38

(52) U.S. Cl. CPC G01R 31/086; H02J 3/38; H02J 2300/24; H02J 2300/28

(57) ABSTRACT

Disclosed is a method and system for quickly identifying and responding weak point-associated power flow based on a sensitivity factor, relating to the technical field of dispatching automation of power system. The method includes: parameter data is acquired, and a transfer factor (SF) matrix is established; consumption and accommodation of new energy of a power distribution network is evaluated, and a line with power flow exceeding a limit is evaluated; and flexible load in the power distribution network is dispatched based on the sensitivity factor, and safety verification is carried out on the result. The present invention identifies a blocking line of the power distribution network, the situation of out of limit of the line is eliminated, so that the safety of the power gird is ensured, and the new energy is consumed and accommodated.

### CROSS-REFERENCE TO RELATED APPLICATIONS

The present application claims priority to Chinese Patent Application No. 2023116110674, filed on Nov. 29, 2023, the entire disclosure of which is incorporated herein by reference.

### TECHNICAL FIELD

The present invention relates to the technical filed of dispatching automation of a power system, in particular to a method for quickly identifying and responding weak point-associated power flow based on a sensitivity factor.

### BACKGROUND

With the fact that a large number of intermittent power generation resources such as wind and solar energy are connected into a power distribution network, due to that a network frame of a power grid in a plateau-mountainous area is weak and not coordinated with consumption and accommodation and carrying capacity of new energy, daytime bidirectional power flow caused by high-proportion new energy with multiple voltage levels connected to the power grid of the plateau-mountainous area triggers operation limit, which causes risks to operation of the power distribution network. In order to simultaneously consider safe operation of the power distribution network and consumption and accommodation of the new energy, a multi-load regulation strategy for quickly identifying and effectively relieving operation weak point-associated power flow may be adopted according to a weak point-associated power flow and user node sensitivity analysis method.

The establishment of a proper line power flow model of the power distribution network is the key for quickly identifying and responding weak point-associated power flow. At present, main line power flow models include an alternating current power flow model and a direct current power flow model. The alternating current power flow model may accurately describe line power flow, but a power flow equation contains a large number of nonlinear items, so that the solving difficulty of problems such as optimal power flow is greatly improved, which causes non-convexification of the problems related to power flow, and the solving efficiency is not ideal. The direct current power flow model is reasonable assumption carried out under the alternating current power flow model, and the alternating current power flow equation is linearized, so that the calculation efficiency is greatly improved. However, it only considers approximate relation between active power flow and voltage phase angle, excessively ideal assumption is carried out on reactive power flow and voltage amplitude, so node voltage often needs to be considered when line power flow of the power distribution network is calculated, and therefore, a large error is generated in a calculation result. In order to simultaneously ensure the accuracy and solving efficiency of the calculation result, a linearized alternating current power flow model between the direct current power flow model and the alternating current power flow model may be provided, and the influence of reactive power and node voltage is considered.

In analysis for weak point-associated power flow and user node sensitivity, a sensitivity index may be adopted for analysis. At present, a sensitivity factor is applied in rapid power flow calculation, based on the direct current power flow model, traditional sensitivity factors include power flow related indexes such as a transfer factor (SF) and a Power Transmission Distribution Factor (PTDF), which may reflect sensitivity of active power flow of a line under a ground state/fault state to active change of a node, and an important role is played in the fields of power flow optimization, safety verification, power system blocking management, and the like. The traditional sensitivity factor is based on the direct current power flow model, the sensitivity of reactive power flow of a line is not considered, so it is not suitable for analyzing alternating current power flow of the power distribution network. Based on the linearized alternating current power flow model, a sensitivity factor system considering reactive power flow and voltage amplitude is provided, based on a LAC-SF and a LAC-PTDF of the LAC model. The weak point-associated power flow is rapidly identified and responded based on the sensitivity factor, so that the safety of the power grid and the consumption and accommodation of the new energy are ensured.

### SUMMARY

In view of the existing problems mentioned above, the present invention is provided.

Therefore, the technical problem to be solved by the present invention is: an existing method for quickly identifying weak point-associated power flow has the problem of grid connection and limitation, and difficulty in considering reactive power flow of a line for accurately analyzing alternating current power flow of a power distribution network.

In order to solve the technical problem mentioned above, the present invention provides the following technical solution: a method for quickly identifying and responding weak point-associated power flow based on a sensitivity factor include: acquiring parameter data and establishing an SF matrix; evaluating consumption and accommodation of new energy of a power distribution network and evaluating a line with power flow exceeding a limit; and dispatching flexible load in the power distribution network based on the sensitivity factor, and carrying out safety verification on the dispatching result.

As a preferred solution of the method for quickly identifying and responding weak point-associated power flow based on a sensitivity factor of the present invention, acquiring parameter data includes acquiring basic load and flexible load of a node, predicating active output data before a wind and solar power day, and taking the acquired data as input data.

As a preferred solution of the method for quickly identifying and responding weak point-associated power flow based on a sensitivity factor of the present invention, establishing an SF matrix includes establishing an SF matrix according to a topology structure of the power distribution network, and linearizing alternating current power flow, expressed as:

$${PL}_{mn} = {g}_{mn} ( {V}_{m} - {V}_{n} ) - {b}_{mn} ( {θ}_{m} - {θ}_{n} ) \\ {QL}_{mn} = - {b}_{mn} ( {V}_{m} - {V}_{n} ) - {g}_{mn} ( {θ}_{m} - {θ}_{n} )$$

wherein PLₘₙ and [symbol] Lₘₙ are active power flow and reactive power flow of the line mn, gₘₙ and bₘₙ are conductivity and susceptance of the line mn, Vₘ and Vₙ are node voltage amplitudes at two ends of the line mn, θₘ and θₙ are node voltage phase angles of two ends of the line mn, and a matrix of node input power and node voltage is expressed as:

$${[ \begin{matrix}{P}_{inj} \\ {Q}_{inj}\end{matrix} ]}_{2 k \times 1} = {{[ \begin{matrix}G & - B \\ - B & = G\end{matrix} ]}_{2 k \times 2 k} [ \begin{matrix}V \\ θ\end{matrix} ]}_{2 k \times 1}$$

wherein Pᵢₙⱼ and Qᵢₙⱼ are active power and reactive power vectors injected at each node, V and θ are voltage amplitude and voltage phase angle vectors of each node, G and B are conductance matrix and susceptance of each node, and after deleting reference nodes, carrying out inversion to obtain a relationship between node voltage and node injected power, expressed as:

$${[ \begin{matrix}V \\ θ\end{matrix} ]}_{2 ( k - 1 ) \times 1} = {{[ \begin{matrix}{K}_{( k - 1 ) \times ( k - 1 )} & {L}_{( k - 1 ) \times ( k - 1 )} \\ {M}_{( k - 1 ) \times ( k - 1 )} & {N}_{( k - 1 ) \times ( k - 1 )}\end{matrix} ]}_{2 ( k - 1 ) \times 2 ( k - 1 )} [ \begin{matrix}{P}_{inj} \\ {Q}_{inj}\end{matrix} ]}_{2 ( k - 1 ) \times 1}$$

K_{(k-1)×(k-1)}, L_{(k-1)×(k-1)}, M_{(k-1)×(k-1)} and N_{(k-1)×(k-1)} are block matrices of an inverse matrix after reference points are deleted, K_{(k×k)}, L_{(k×k)}, M_{(k×k)} and N_{(k×k)} may be obtained by zeroing rows and columns corresponding to a reference node, k is the total number of the node of a system, and calculating an SF between active power of a line and active power of the node, expressed as:

$$\begin{matrix}{SF}_{p - p}^{m - n , i} = \frac{\partial {PL}_{mn}}{\partial {P}_{i}} \\ = \frac{\partial ( {g}_{mn} ( {V}_{m} - {V}_{n} ) - {b}_{mn} ( {θ}_{m} - {θ}_{n} ) )}{\partial {P}_{i}} \\ = {g}_{mn} ( \frac{\partial {V}_{m}}{\partial {P}_{i}} - \frac{\partial {V}_{n}}{\partial {P}_{i}} ) - {b}_{mn} ( \frac{\partial {θ}_{m}}{\partial {P}_{i}} - \frac{\partial {θ}_{n}}{\partial {P}_{i}} ) \\ = {g}_{mn} ( {K}_{m , i} - {K}_{n , i} ) - {b}_{mn} ( {M}_{m , i} - {M}_{n , i} )\end{matrix}$$

Pᵢ is an active power vector of the node i, K_{m,i} and K_{n,i} is the element in the voltage amplitude-active sensitivity matrix K_{(k×k)}, representing sensitivity of voltage amplitudes of node m and n to injected active power of the node i; and M_{m,i} and M_{n,i} are elements in a voltage phase angle-active sensitivity matrix M_{(k×k)}, representing the sensitivity of voltage phase angles of node m and n node to injected active power of the node i.

As a preferred solution of the method for quickly identifying and responding weak point-associated power flow based on a sensitivity factor of the present invention, evaluating consumption and accommodation of new energy of a power distribution network includes establishing a new energy consumption and accommodation evaluation model based on the sensitivity factor, and the new energy consumption and accommodation evaluation model includes a target function and a constraint condition.
the target function is expressed as:

$$max {\sum }_{i = 1}^{{N}_{r}} {pr}_{i}$$

wherein prᵢ is actual active output of new energy of node i;
the constraint condition comprises active balance constraint of the system:

$${p}_{i} = {pd}_{i} - {pr}_{i} \\ {q}_{i} = {qd}_{i}$$

wherein pᵢ and qᵢ are outflow active power and reactive power of the node i, pdᵢ is an active load of the node i, qdᵢ is a reactive load of the node i, and active and reactive power flow constraint of the line j is expressed as:

$$PL = - ( {SF}_{p - p} {P}_{i} + {SF}_{p - q} {Q}_{i} ) \\ QL = - ( {SF}_{q - p} {P}_{i} + {SF}_{q - q} {Q}_{i} ) \\ {PL}_{j}^{2} + {QL}_{j}^{2} \leq {SL}_{j , max}$$

wherein SF_{q-p} represents the transfer factor (SF) matrix between reactive power of the line and active power of the node, SFₚ₋ₚ represents the transfer factor (SF) matrix between active power of the line and active power of the node, SF_{p-q} represents the transfer factor (SF) matrix between active power of the line and reactive power of the node, SF_{q-q} represents the transfer factor (SF) matrix between reactive power of the line and reactive power of the node Qᵢ, represents outflow reactive power vector of the node i, PLⱼ and [symbol] Lⱼ are active and reactive power flow of the line j, SL_{j,max} represents maximum line capacity of the line j, PL and QL are active and reactive pow flow vectors of the line, and voltage constraint is expressed as:

$${V}_{0} = 1 \\ {V}_{j , m} - {V}_{j , n} = {r}_{j} \cdot {PL}_{j} + {x}_{j} \cdot {QL}_{j} \\ 0.9 \leq V \leq 1.1$$

wherein rⱼ and xⱼ are resistance and reactance of the line j, and actual active output constraint of new energy is expressed as:

$$0 \leq {pr}_{i} \leq {pr}_{i , max}$$

wherein pr_{i,max} is active output maximum of new energy of the node i, modifying the new energy consumption and accommodation evaluation model, the constraint of capacity limit of line power flow is not considered, a line with power flow exceeding a limit when the consumption and accommodation of new energy is the maximum is obtained, and calculating relative out-of-limit degree of line power flow.

As a preferred solution of the method for quickly identifying and responding weak point-associated power flow based on a sensitivity factor of the present invention, calculating relative out-of-limit degree of the line power flow is expressed as:

$${σ}_{j} = \frac{{SL}_{j}}{{SL}_{j , max}} \times 100 \%$$

wherein SLⱼ represents maximal line capacity of the line j;
determining a load impact sensitivity entropy, expressed as:

$${H}_{j} = - c {\sum }_{i = 1}^{N} \frac{\vert {SF}_{P - P} ( j , i ) \vert}{{\sum }_{j = 1}^{{N}_{br}} \vert {SF}_{P - P} ( j , i ) \vert} ln \frac{\vert {SF}_{P - P} ( j , i ) \vert}{{\sum }_{j = 1}^{{N}_{br}} \vert {SF}_{P - P} ( j , i ) \vert}$$

selecting a weak point line, expressed as:

$$Γ = \{ Γ ∈ Line \vert {SL}_{Γ} = max ( {σ}_{j} ) and max ( {H}_{j} ) \}$$

wherein Hⱼ represents a load impact sensitivity entropy corresponding to line j.

As a preferred solution of the method for quickly identifying and responding weak point-associated power flow based on a sensitivity factor of the present invention, dispatching flexible load in the power distribution network based on the sensitivity factor includes: judging whether the direction of the line power flow is consistent with an assumed positive direction or not, assuming that reactive power flow of the line does not change, obtaining an out-of-limit active power flow value ΔPLⱼ of the line, dispatching a node belonging to flexible load, so that the line exceeding a limit returns to normal, the safety of the power grid is ensured, new energy is consumed and accommodated, and establishing an optimization model with minimum dispatching amount of the flexible load, expressed as:

$$min {\sum }_{i = 1}^{{N}_{fd}} Δ {P}_{i}^{fd}$$

$${\sum }_{i = 1}^{{N}_{fd}} - {SF}_{p - p} ( j , {i}^{fd} ) \cdot Δ {P}_{i}^{fd} \geq αΔ {PL}_{j}$$

$$0 \leq Δ {P}_{i}^{fd} \leq Δ {P}_{i , max}^{fd}$$

Wherein N_{fd} is the total number of flexible load of the system, ΔPᵢ^{fd} is adjusting amount of active power of the ith flexible load, i^{fd} is the position, corresponding in the node of the system, of the ith flexible load, ΔP_{l,max}^{fd} is the maximum value of the adjusting amount of the ith flexible load, and α is an adjusting parameter set for the power flow out-of-flow value of the corresponding line j.

As a preferred solution of the method for quickly identifying and responding weak point-associated power flow based on a sensitivity factor of the present invention, carrying out safety verification on the dispatching result includes: carrying out safety verification on line power flow of the system with flexible load of the node dispatched, if a situation of out of limit of the line exists, re-evaluating the line exceeding a limit, and dispatching remaining dispatchable flexible load capacity so that the line power flow is in a safety range.

Another objective of the present invention is to provide a system for quickly identifying and responding weak point-associated power flow based on a sensitivity factor, which may carry out sensitivity analysis on weak point-associated power flow and a user node of flexible load based on the sensitivity factor, and may enable the situation of out of limit of the line to be eliminated by dispatching flexible load of the corresponding node, so that the safety of the power gird is ensured, the new energy is consumed and accommodated, and the problem that the existing method for quickly identifying weak point-associated power flow doses not consider reactive power flow of the line and is not suitable for carrying out accurate analysis on alternating current power flow of the power distribution network is solved.

As a preferred solution of the system for quickly identifying and responding weak point-associated power flow based on a sensitivity factor of the present invention, the system includes: a data acquisition module, an evaluation module and a dispatching and verification module. The data acquisition module is configured to acquire parameter data and establish a SF matrix; the evaluation module is configured to evaluate consumption and accommodation of new energy of the power distribution network and evaluate a line with power flow exceeding a limit; and the dispatching and verification module is configured to dispatch flexible load in the power distribution network based on the sensitivity factor, and carry out safety verification on the dispatching result.

A computer device includes a memory and a processor, a computer program is stored on the memory, and when the computer program is executed by the processor, the steps of the method for quickly identifying and responding weak point-associated power flow based on a sensitivity factor are implemented.

A computer-readable storage medium, having stored thereon a computer program which, when executed by a processor, implements the steps of the method for quickly identifying and responding weak point-associated power flow based on a sensitivity factor.
the present invention has the beneficial effects that: the method for quickly identifying and responding weak point-associated power flow based on a sensitivity factor provided by the present invention identifies a weak point of consumption and accommodation of new energy of the power distribution network, a blocking line that blocks consumption and accommodation of new energy is obtained, then a basis is provided for following accurate regulation of flexible load, and a theoretical support is provided for capacity transformation of the line in the future. Sensitivity analysis is carried out on weak point-associated power flow and the user nodes of flexible load based on the sensitivity factor, the situation of out of limit of the line is eliminated by dispatching flexible load of the corresponding node, so that the safety of the power gird is ensured, and the new energy is consumed and accommodated. The present invention obtains better effects in the aspects of safety, applicability and accuracy.

### BRIEF DESCRIPTION OF DRAWINGS

In order to describe the technical solutions in the embodiments of the present invention more clearly, the drawings required to be used in description of the embodiments will be simply introduced below, obviously, the drawings described below are only some embodiments of the present invention, and other drawings can further be obtained by those of ordinary skill in the art according to the drawings without creative work.

FIG. 1 is an overall flow chart of a method for quickly identifying and responding weak point-associated power flow based on a sensitivity factor provided by a first embodiment of the present invention;

FIG. 2 is a diagram showing condition before and after line power flow dispatching of a system at a certain moment of a method for quickly identifying and responding weak point-associated power flow based on a sensitivity factor provided by a second embodiment of the present invention;

FIG. 3 is a diagram showing consumption and accommodation condition of new energy before and after dispatching at a certain moment of a method for quickly identifying and responding weak point-associated power flow based on a sensitivity factor provided by a second embodiment of the present invention; and

FIG. 4 is an overall flow chart of a system for quickly identifying and responding weak point-associated power flow based on a sensitivity factor provided by a third embodiment of the present invention.

### DETAILED DESCRIPTION OF THE EMBODIMENTS

In order to make the aforementioned purposes, features and advantages of the present invention more apparent and comprehensible, detailed descriptions of specific implementation modes of the present invention are provided below in conjunction with the appended drawings. It is apparent that the described embodiments are merely a part of the embodiments of the present invention, rather than all embodiments. Based on the embodiments of the present invention, all other embodiments obtained by those of ordinary skill in the art without creative efforts shall fall within the protection scope of the present invention.

### Embodiment 1

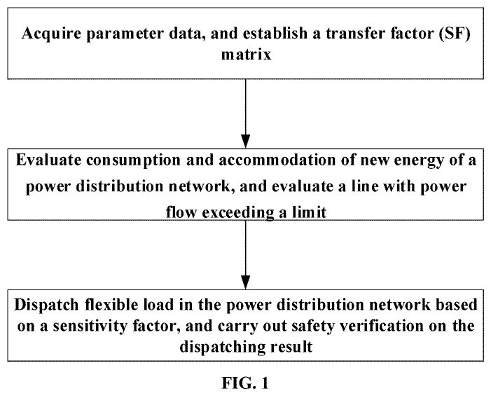

Referring to FIG. 1, an embodiment of the present invention provides a method for quickly identifying and responding weak point-associated power flow based on a sensitivity factor, which includes:

S1: parameter data is acquired, and an SF matrix is established.

Furthermore, parameter data is acquired includes that basic load and flexible load of a node are acquired, active output data is predicated before a wind and solar power day, and the acquired data is taken as input data. The establishment of the SF matrix is beneficial for understanding interaction among different nodes, so that resources of a power grid may be more effectively managed and dispatched.

It is to be noted that an SF matrix (LAC-SF matrix) is established according to a topology structure of a power distribution network, and a preparation is made for calculating power flow of the power distribution network later. The LAC-SF matrix of the power distribution network contains all information of the network topology, with each row representing a power transmission line and each column representing a node. A matpower toolbox in Matlab may provide basic data (correspondence of node and line, impedance parameters of lines, etc.) of network topology, and a makeSF function is called to obtain the LAC-SF matrix of the power distribution network.

It is also to be noted that an SF matrix is established includes that an SF matrix is established according to a topology structure of the power distribution network, and alternating current power flow is linearized, expressed as:

$${PL}_{mn} = {g}_{mn} ( {V}_{m} - {V}_{n} ) - {b}_{mn} ( {θ}_{m} - {θ}_{n} )$$

$${QL}_{mn} = - {b}_{mn} ( {V}_{m} - {V}_{n} ) - {g}_{mn} ( {θ}_{m} - {θ}_{n} )$$

wherein PLₘₙ and [symbol] Lₘₙ are active power flow and reactive power flow of the line mn, gₘₙ and bₘₙ are conductivity and susceptance of the line mn, Vₘ and Vₙ are node voltage amplitudes at two ends of the line mn, θₘ and θₙ are node voltage phase angles of two ends of the line mn, and a matrix of node input power and node voltage is expressed as:

$${[ \begin{matrix}{P}_{inj} \\ {Q}_{inj}\end{matrix} ]}_{2 k \times 1} = {{[ \begin{matrix}G & - B \\ - B & - G\end{matrix} ]}_{2 k \times 2 k} [ \begin{matrix}V \\ θ\end{matrix} ]}_{2 k \times 1}$$

wherein Pᵢₙⱼ and Qᵢₙⱼ are active power and reactive power vectors injected at each node, V and θ are voltage amplitude and voltage phase angle vectors of each node, G and B are conductance matrix and susceptance of each node, and after deleting reference nodes, carrying out inversion to obtain a relationship between node voltage and node injected power, expressed as:

$${[ \begin{matrix}V \\ θ\end{matrix} ]}_{2 ( k - 1 ) \times 1} = {{[ \begin{matrix}{K}_{( k - 1 ) \times ( k - 1 )} & {L}_{( k - 1 ) \times ( k - 1 )} \\ {M}_{( k - 1 ) \times ( k - 1 )} & {N}_{( k - 1 ) \times ( k - 1 )}\end{matrix} ]}_{2 ( k - 1 ) \times 2 ( k - 1 )} [ \begin{matrix}{P}_{inj} \\ {Q}_{inj}\end{matrix} ]}_{2 ( k - 1 ) \times 1}$$

K_{(k-1)×(k-1)}, L_{(k-1)×(k-1)}, M_{(k-1)×(k-1)} and N_{(k-1)×(k-1)} are block matrices of an inverse matrix after reference points are deleted, K_{(k×k)}, L_{(k×k)}, M_{(k×k)} and N_{(k×k)} may be obtained by zeroing rows and columns corresponding to a reference node, and k represents the total number of the node of a system, and an SF between active power of a line and active power of a node is calculated, expressed as:

$${SF}_{p - p}^{m - n , i} = \frac{\partial {PL}_{mn}}{\partial {P}_{i}} = \frac{\partial ( {g}_{mn} ( {V}_{m} - {V}_{n} ) - {b}_{mn} ( {θ}_{m} - {θ}_{n} ) )}{\partial {P}_{i}} = {g}_{mn} ( \frac{\partial {V}_{m}}{\partial {P}_{i}} - \frac{\partial {V}_{n}}{\partial {P}_{i}} ) - {b}_{mn} ( \frac{\partial {θ}_{m}}{\partial {P}_{i}} - \frac{\partial {θ}_{n}}{\partial {P}_{i}} ) = {g}_{mn} ( {K}_{m , i} - {K}_{n , i} ) - {b}_{mn} ( {M}_{m , i} - {M}_{n , i} )$$

wherein Pi is active power vector of a system injected at node i, K_{m,i} and K_{n,i} are elements in a voltage amplitude-active sensitivity matrix K_{(k×k)}, representing sensitivity of voltage amplitudes of node m and n to injected active power of the node i; and M_{m,i} and M_{n,i} are elements in a voltage phase angle-active sensitivity matrix M_{(k×k)}, representing the sensitivity of voltage phase angles of node m and node n to injected active power of the node i. By evaluating consumption and accommodation capacity of new energy and a line with power flow exceeding a limit, a power grid operator may be helped to identify potential risks and weak point, so that appropriate measures are taken to improve reliability and efficiency of the power grid.

S2: consumption and accommodation of new energy of the power distribution network is evaluated and a line with power flow exceeding a limit is evaluated.

Furthermore, consumption and accommodation of new energy of the power distribution network is evaluated includes that a new energy consumption and accommodation evaluation model is established based on a sensitivity factor, and the new energy consumption and accommodation evaluation model includes a target function and a constraint condition.
the target function is expressed as:

$$max {\sum }_{i = 1}^{{N}_{r}} {pr}_{i}$$

wherein prᵢ is actual active output of new energy of node i;
the constraint condition comprises active balance constraint of the system:

$${p}_{i} = {pd}_{i} - {pr}_{i}$$

$${q}_{i} = {qd}_{i}$$

wherein pᵢ and qᵢ are outflow active power and reactive power of the node i, pdᵢ is an active load of the node i, qdᵢ is a reactive load of the node i, and active and reactive power flow constraint of the line j is expressed as:

$$P L = - ( {SF}_{p - p} {P}_{i} + S {F}_{p - q} {Q}_{i} )$$

$$QL = - ( S {F}_{q - p} {P}_{i} + S {F}_{q - q} {Q}_{i} )$$

$${PL}_{j}^{2} + {QL}_{j}^{2} \leq {SL}_{j , max}$$

wherein SF_{q-p} represents the transfer factor (SF) matrix between reactive power of the line and active power of the node, SFₚ₋ₚ represents the transfer factor (SF) matrix between active power of the line and active power of the node, SF_{p-q} represents the transfer factor (SF) matrix between active power of the line and reactive power of the node, SF_{q-q} represents the transfer factor (SF) matrix between reactive power of the line and reactive power of the node, Qᵢ represents outflow reactive power vector of the node i, PLⱼ and [symbol] Lⱼ are active and reactive power flow of the line j, SL_{j,max} represents maximum line capacity of the line j, PL and QL are active and reactive pow flow vectors of the line, and voltage constraint is expressed as:

$${V}_{0} = 1$$

$${V}_{j , m} - {V}_{j , n} = {r}_{j} \cdot {PL}_{j} + {x}_{j} \cdot {QL}_{j}$$

$$0.9 \leq V \leq 1.1$$

wherein rⱼ and xⱼ are resistance and reactance of the line j, and actual active output constraint of new energy is expressed as:

$$0 \leq {pr}_{i} \leq {pr}_{i , max}$$

wherein pr_{i,max} is active output maximum of new energy of the node i, modifying the new energy consumption and accommodation evaluation model, the constraint of capacity limit of line power flow is not considered, a line with power flow exceeding a limit when the consumption and accommodation of new energy is the maximum is obtained, and calculating relative out-of-limit degree of line power flow.

It is to be noted that calculation of relative out-of-limit degree of line power flow is expressed as:

$${σ}_{j} = \frac{SL}{{SL}_{j , max}} \times 100 \%$$

wherein: SLⱼ represents maximal line capacity of the line j;
determining a load impact sensitivity entropy, expressed as:

$${H}_{j} = - c {\sum }_{i = 1}^{N} \frac{\vert {SF}_{P - P} ( j , i ) \vert}{{\sum }_{j = 1}^{{N}_{br}} \vert {SF}_{P - P} ( j , i ) \vert} ln \frac{\vert {SF}_{P - P} ( j , i ) \vert}{{\sum }_{j = 1}^{{N}_{br}} \vert {SF}_{P - P} ( j , i ) \vert}$$

selecting a weak point line, expressed as:

$$Γ = \{ Γ ∈ Line \vert {SL}_{Γ} = max ( {σ}_{j} ) and max ( {H}_{j} ) \}$$

wherein Hⱼ represents a load impact sensitivity entropy corresponding to line j. By calculating relative out-of-limit degree of line power flow, a vulnerable link in the power grid may be rapidly identified, and important decision support is provided for optimization and upgrading of the power grid.

S3: flexible load in the power distribution network is dispatched based on the sensitivity factor, and safety verification is carried out on the dispatching result.

Furthermore, flexible load in the power distribution network is dispatched based on the sensitivity factor includes: whether the direction of line power flow is consistent with an assumed positive direction or not is judged, assuming that reactive power flow of the line does not change, an out-of-limit active power flow value ΔPLⱼ of the line is obtained, a node belonging to flexible load is dispatched, so that the line exceeding a limit returns to normal, the safety of the power grid is ensured, new energy is consumed and accommodated, and an optimization model is established with minimum dispatching amount of flexible load, expressed as:

$$min {\sum }_{i = 1}^{{N}_{fd}} Δ {P}_{i}^{fd} \\ {\sum }_{i = 1}^{{N}_{fd}} - {SF}_{p - p} ( j , {i}^{fd} ) \cdot Δ {P}_{i}^{fd} \geq αΔ {PL}_{j} \\ 0 \leq Δ {P}_{i}^{fd} \leq Δ {P}_{i , max}^{fd}$$

wherein N_{fd} is the total number of flexible load of the system, ΔPᵢ^{fd} is adjusting amount of active power of the ith flexible load, i^{fd} is the position, corresponding in the node of the system, of the ith flexible load, ΔP_{i,max}^{fd} is the maximum value of the adjusting amount of the ith flexible load, and α is an adjusting parameter set for the power flow out-of-flow value of the corresponding line j.

It is to be noted that safety verification is carried out on the dispatching result includes: safety verification is carried out on line power flow of a system with flexible load of a node dispatched, if a situation of out of limit of the line exists, the line exceeding a limit is re-evaluated, and remaining dispatchable flexible load capacity is dispatched so that the line power flow is in a safety range.

### Embodiment 2

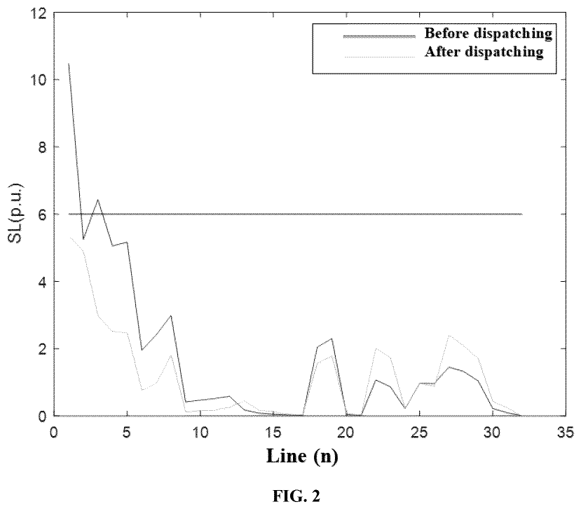

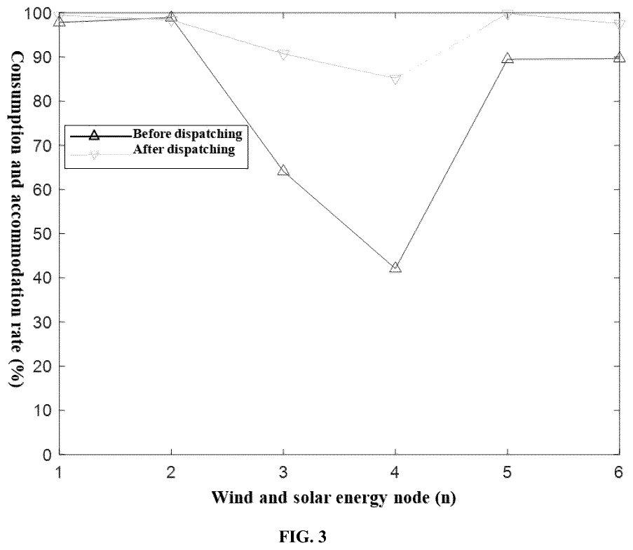

Referring to FIGS. 2-3, an embodiment of disclosure provides a method for quickly identifying and responding weak point-associated power flow based on a sensitivity factor. In order to verify the beneficial effects of the present invention, scientific demonstration is performed through economic benefit calculation and a simulation experiment.

First, the experiment is carried out on the basis of an IEEE33 system, nodes 4, 6, 9, 13, 20 and 27 are selected as new energy access nodes, and the condition of consumption and accommodation hindering of new energy at a certain moment is selected for analysis. Data of load and wind and solar power is input, a transfer factor matrix is calculated based on a network topology of the IEEE33 system, in consideration of line constraint, under the condition that the consumption and accommodation rate of new energy of the system is the maximum, new energy consumption and accommodation connected to the node of new energy is evaluated, new energy is completely accommodated under the condition that the line constraint is not considered, the condition of the line with power flow exceeding a limit is evaluated, the degree of out of limit and a load shock sensitivity entropy are calculated, a line blocking consumption and accommodation of new energy is identified, dispatching of the flexible load is carried out according to the method provided above, safety verification is carried out, the dispatching amount of the flexible load is output if requirements are met, otherwise, load adjusting is further carried out till safety verification is satisfied.

FIG. 2 represents change condition of line power flow before and after dispatching, and the red line represents the condition of line power flow obtained by S4; and the green line represents the condition of line power flow after safety verification is passed and after load dispatching is carried out. Through comparison and analysis, the dispatching solution of flexible load provided herein may enable the condition of out of limit of the line power flow to return to normal, which indicates that the dispatching result of flexible load is effective, and then consumption and accommodation of new energy is promoted.

FIG. 3 represents change of consumption and accommodation rate of new energy of six nodes of new energy before and after dispatching, through comparison, it is found that the dispatching solution of flexible load provided herein may enable the consumption and accommodation rate of new energy of the node with consumption and accommodation of new energy hinged to be improved, so that rapid identification and response for power flow related to a new energy consumption and accommodation weak point are realized.

### Embodiment 3

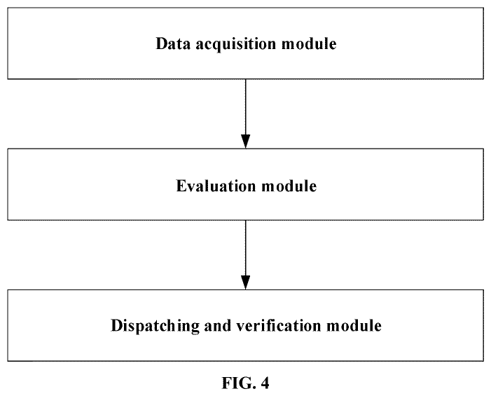

Referring to FIG. 4, an embodiment of the present invention provides a system for quickly identifying and responding weak point-associated power flow based on a sensitivity factor, which includes a data acquisition module, an evaluation module and a dispatching and verification module.

The data acquisition module is configured to acquire parameter data and establish an SF matrix; the evaluation module is configured to evaluate consumption and accommodation of new energy of a power distribution network and evaluate a line with power flow exceeding a limit; and the dispatching and verification module is configured to dispatch flexible load in the power distribution network based on the sensitivity factor, and carry out safety verification on the dispatching result.

If a function is implemented in a form of a software functional unit, and sold or used as an independent product, the function may be stored in a computer-readable storage medium. Based on this understanding, the technical solution of the present invention essentially or a part that contributes to the prior art, or part of the technical solution may be embodied in a form of a software product; and the computer software product is stored in a storage medium and includes a plurality of instructions which are used to enable a computer device (which may be a personal computer, a server, or a network device, etc.) to execute all or part of the steps of the methods described in the various embodiments of the present invention. The foregoing storage medium includes any medium that may store program codes, such as a U disk, a removable hard disk, a Read-Only Memory (ROM), a Random Access Memory (RAM), a magnetic disk, or an optical disc.

Logics and/or steps expressed in the flow chart or otherwise described herein, for example, may be considered as a sequence table of executable instructions for implementing logical functions, and may be implemented in any computer-readable medium for use by instruction execution systems, apparatuses, or devices (such as computer-based systems, systems including processors, or other systems that may acquire instructions from the instruction execution systems, the apparatuses, or the devices and execute the instructions), or in a combination manner. For the purposes of this specification, the “computer-readable medium” may be any apparatus that may contain, store, communicate, propagate or transmit a program for use by the instruction execution systems, the apparatuses, or the devices or in a combination manner.

More specific examples (non-exhaustive list) of the computer-readable medium may include the following: an electrical connection (an electronic apparatus) with one or more wires, a portable computer disk case (a magnetic apparatus), a Random Access Memory (RAM), a Read-Only Memory (ROM), an Erasable Programmable Read-Only Memory (EPROM or flash memory), an optical fiber, and a portable Compact Disk Read-Only Memory (CDROM). In addition, the computer-readable medium may even be paper or other appropriate media on which the program may be printed, it because that the program may be acquired electronically, for example, by optically scanning the paper or other media, followed by editing, interpretation or, if necessary, other appropriate processing ways, and then stored in a computer memory.

It should be understood that each part of the present invention be achieved by hardware, software, firmware or a combination thereof. In the above implementation mode, multiple steps or methods can be implemented with the software or the firmware stored in the memory and executed by the appropriate instruction execution system. For example, if they are implemented by the hardware, as in another implementation mode, they may be implemented by any one of the following technologies well known in the art or their combination: a discrete logic circuit with a logic gate circuit for implementing a logic function of a data signal, a special integrated circuit with an appropriate combinational logic gate circuit, a Programmable Gate Array (PGA), a Field Programmable Gate Array (FPGA), etc. It should be noted that the above embodiments are only used to illustrate the technical solution of the present invention and are not for limitation. Although the present invention is described in detail with reference to the preferred embodiments, those of ordinary skill in the art should understand that the technical solutions of the present invention may be modified or replaced by equivalents without departing from the spirit and scope of the technical solutions of the present invention, and all those modifications or replacements should be included in the scope of the claims of the present invention.

It should be noted that, the above examples are merely used for illustrating the technical solution of the present invention and are not for limitation, although the present invention is described in detail with reference to the preferred examples, those of ordinary skill in the art should understand that, the technical solutions of the present invention may be modified or equivalently substituted without departing from the spirit and scope of the technical solution of the present invention, and all those modifications or replacements should be included in the scope of the claims of the present invention.

What is claimed is:

1. A method for quickly identifying and responding weak point-associated power flow based on a sensitivity factor, comprising:
acquiring parameter data, and establishing a transfer factor (SF) matrix;
evaluating consumption and accommodation of new energy of a power distribution network, and evaluating a line with power flow exceeding a limit; and
dispatching flexible load in the power distribution network based on the sensitivity factor, and carrying out safety verification on the dispatching result.

2. The method for quickly identifying and responding weak point-associated power flow based on a sensitivity factor of claim 1, wherein acquiring parameter data comprises acquiring basic load and flexible load of a node, predicating active output data before a wind and solar power day, and taking the acquired data as input data.

3. The method for quickly identifying and responding weak point-associated power flow based on a sensitivity factor of claim 2, wherein establishing an SF matrix comprises establishing an SF matrix according to a topology structure of the power distribution network, and linearizing alternating current power flow, expressed as:
$${PL}_{mn} = {g}_{mn} ( {V}_{m} - {V}_{n} ) - {b}_{mn} ( {θ}_{m} - {θ}_{n} ) \\ {QL}_{mn} = - {b}_{mn} ( {V}_{m} - {V}_{n} ) - {g}_{mn} ( {θ}_{m} - {θ}_{n} )$$
wherein PLₘₙ and [symbol] Lₘₙ are active power flow and reactive power flow of the line mn, gₘₙ and bₘₙ are conductivity and susceptance of the line mn, Vₘ and Vₙ are node voltage amplitudes at two ends of the line mn, θₘ and θₙ are node voltage phase angles of two ends of the line mn, and a matrix of node input power and node voltage is expressed as:
$${[ \begin{matrix}{P}_{inj} \\ {Q}_{inj}\end{matrix} ]}_{2 k \times 1} = {{[ \begin{matrix}G & - B \\ - B & - G\end{matrix} ]}_{2 k \times 2 k} [ \begin{matrix}V \\ θ\end{matrix} ]}_{2 k \times 1}$$
wherein Pᵢₙⱼ and Qᵢₙⱼ are active power and reactive power vectors injected at each node, V and θ are voltage amplitude and voltage phase angle vectors of each node, G and B are conductance matrix and susceptance of each node, and after deleting reference nodes, carrying out inversion to obtain a relationship between node voltage and node injected power, expressed as:
$${[ \begin{matrix}V \\ θ\end{matrix} ]}_{2 ( k - 1 ) \times 1} = {{[ \begin{matrix}{K}_{( k - 1 ) \times ( k - 1 )} & {L}_{( k - 1 ) \times ( k - 1 )} \\ {M}_{( k - 1 ) \times ( k - 1 )} & {N}_{( k - 1 ) \times ( k - 1 )}\end{matrix} ]}_{2 ( k - 1 ) \times 2 ( k - 1 )} [ \begin{matrix}{P}_{inj} \\ {Q}_{inj}\end{matrix} ]}_{2 ( k - 1 ) \times 1}$$
wherein K_{(k-1)×(k-1)}, L_{(k-1)×(k-1)}, M_{(k-1)×(k-1)} and N_{(k-1)×(k-1)} are block matrices of an inverse matrix after reference points are deleted, K_{(k×k)}, L_{(k×k)}, M_{(k×k)} and N_{(k×k)} may be obtained by zeroing rows and columns corresponding to a reference node, k is the total number of the node of a system, and calculating an SF between active power of the line and active power of the node, expressed as:
$${SF}_{p - p}^{m - n , i} = \frac{\partial {PL}_{mn}}{\partial {P}_{i}} = \frac{\partial ( {g}_{mn} ( {V}_{m} - {V}_{n} ) - {b}_{mn} ( {θ}_{m} - {θ}_{n} ) )}{\partial {P}_{i}} = {g}_{mn} ( \frac{\partial {V}_{m}}{\partial {P}_{i}} - \frac{\partial {V}_{n}}{\partial {P}_{i}} ) - {b}_{mn} ( \frac{\partial {θ}_{m}}{\partial {P}_{i}} - \frac{\partial {θ}_{n}}{\partial {P}_{i}} ) = {g}_{mn} ( {K}_{m , i} - {K}_{n , i} ) - {b}_{mn} ( {M}_{m , i} - {M}_{n , i} )$$
wherein Pi is active power vector of a system injected at node i, K_{m,i} and K_{n,i} are elements in a voltage amplitude-active sensitivity matrix K_{(k×k)}, representing sensitivity of voltage amplitudes of node m and n to injected active power of the node i; and M_{m,i} and M_{n,i} are elements in a voltage phase angle-active sensitivity matrix M_{(k×k)}, representing the sensitivity of voltage phase angles of node m and node n to injected active power of the node i.

4. The method for quickly identifying and responding weak point-associated power flow based on a sensitivity factor of claim 3, wherein evaluating consumption and accommodation of new energy of a power distribution network comprises establishing a new energy consumption and accommodation evaluation model based on a sensitivity factor, and the new energy consumption and accommodation evaluation model comprises a target function and a constraint condition;
the target function is expressed as:
$$max {\sum }_{i = 1}^{{N}_{r}} {pr}_{i}$$
wherein prᵢ is actual active output of new energy of node i;
the constraint condition comprises active balance constraint of the system:
$${p}_{i} = {pd}_{i} - {pr}_{i} \\ {q}_{i} = {qd}_{i}$$
wherein pᵢ and qᵢ are outflow active power and reactive power of the node i, pdᵢ is an active load of the node i, qdᵢ is a reactive load of the node i, and active and reactive power flow constraint of the line j is expressed as:
$$P L = - ( {SF}_{p - p} {P}_{i} + S {F}_{p - q} {Q}_{i} ) \vert QL = - ( S {F}_{q - p} {P}_{i} + {SF}_{q - q} {Q}_{i} ) \\ {PL}_{j}^{2} + {QL}_{j}^{2} \leq {SL}_{j , max}$$
wherein SF_{q-p} represents the transfer factor (SF) matrix between reactive power of the line and active power of the node, SFₚ₋ₚ represents the transfer factor (SF) matrix between active power of the line and active power of the node, SF_{p-q} represents the transfer factor (SF) matrix between active power of the line and reactive power of the node, SF_{q-q} represents the transfer factor (SF) matrix between reactive power of the line and reactive power of the node, Qᵢ represents outflow reactive power vector of the node i, PLⱼ and [symbol] Lⱼ are active and reactive power flow of the line j, SL_{j,max} represents maximum line capacity of the line j, PL and QL are active and reactive pow flow vectors of the line, and voltage constraint is expressed as:
$${V}_{0} = 1 \\ {V}_{j , m} - {V}_{j , n} = {r}_{j} \cdot {PL}_{j} + {x}_{j} \cdot {QL}_{j} \\ 0.9 \leq V \leq 1.1$$
wherein rⱼ and xⱼ are resistance and reactance of the line j, and actual active output constraint of new energy is expressed as:
$$0 \leq {pr}_{i} \leq {pr}_{i , max}$$
wherein pr_{i,max} is active output maximum of new energy of the node i, modifying the new energy consumption and accommodation evaluation model, the constraint of capacity limit of line power flow is not considered, a line with power flow exceeding a limit when the consumption and accommodation of new energy is the maximum is obtained, and calculating relative out-of-limit degree of line power flow.

5. The method for quickly identifying and responding weak point-associated power flow based on a sensitivity factor of claim 4, wherein calculating relative out-of-limit degree of line power flow of the line is expressed as:
$${σ}_{j} = \frac{S {L}_{j}}{S {L}_{j , max}} \times 100 \%$$
wherein SLⱼ represents maximal line capacity of the line j;
determining a load impact sensitivity entropy, expressed as:
$${H}_{j} = - c {\sum }_{i = 1}^{N} \frac{\vert {SF}_{P - P} ( j , i ) \vert}{{\sum }_{j = 1}^{{N}_{br}} \vert {SF}_{P - P} ( j , i ) \vert} ln \frac{\vert {SF}_{P - P} ( j , i ) \vert}{{\sum }_{j = 1}^{{N}_{br}} \vert {SF}_{P - P} ( j , i ) \vert}$$
selecting a weak point line, expressed as:
$$Γ = \{ Γ ∈ Line \vert {SL}_{Γ} = max ( {σ}_{j} ) and max ( {H}_{j} ) \}$$
wherein Hⱼ represents a load impact sensitivity entropy corresponding to line j.

6. The method for quickly identifying and responding weak point-associated power flow based on a sensitivity factor of claim 5, wherein dispatching flexible load in the power distribution network based on the sensitivity factor comprises: judging whether the direction of line power flow is consistent with an assumed positive direction or not, assuming that reactive power flow of the line does not change, obtaining an out-of-limit active power flow value ΔPLⱼ of the line, dispatching a node belonging to flexible load, so that the line exceeding a limit returns to normal, the safety of a power grid is ensured, new energy is consumed and accommodated, and establishing an optimization model with minimum dispatching amount of flexible load, expressed as:
$$min {\sum }_{i = 1}^{{N}_{fd}} Δ {P}_{i}^{fd} \\ {\sum }_{i = 1}^{{N}_{fd}} - {SF}_{p - p} ( j , {i}^{fd} ) \cdot Δ {P}_{i}^{fd} \geq αΔ {PL}_{j} \\ 0 \leq Δ {P}_{i}^{fd} \leq Δ {P}_{i , max}^{fd}$$
wherein N_{fd} is the total number of flexible load of the system, ΔPᵢ^{fd} is adjusting amount of active power of the ith flexible load, i^{fd} is the position, corresponding in the node of the system, of the ith flexible load, ΔP_{i,max}^{fd} is the maximum value of the adjusting amount of the ith flexible load, and α is an adjusting parameter set for the power flow out-of-flow value of the corresponding line j.

7. The method for quickly identifying and responding weak point-associated power flow based on a sensitivity factor of claim 6, wherein carrying out safety verification on the dispatching result comprises: carrying out safety verification on line power flow of a system with flexible load of a node dispatched, if a situation of out of limit of the line exists, re-evaluating the line exceeding a limit, and dispatching remaining dispatchable flexible load capacity so that the line power flow is in a safety range.

8. A system adopting the method for quickly identifying and responding weak point-associated power flow based on a sensitivity factor of claim 1, comprising a data acquisition module, an evaluation module and a dispatching and verification module, wherein
the data acquisition module is configured to acquire parameter data, and establish an SF matrix;
the evaluation module is configured to evaluate consumption and accommodation of new energy of a power distribution network, and evaluate a line with power flow exceeding a limit; and
the dispatching and verification module is configured to dispatch flexible load in the power distribution network based on the sensitivity factor, and carry out safety verification on the dispatching result.

9. A computer device, comprising a memory and a processor, the memory storing a computer program, wherein when the computer program is executed by the processor, the steps of the method for quickly identifying and responding weak point-associated power flow based on a sensitivity factor of claim 1 are implemented.

10. A computer-readable storage medium, having stored thereon a computer program which, when executed by a processor, implements the steps of the method for quickly identifying and responding weak point-associated power flow based on a sensitivity factor of claim 1.
